(19) United States
(12) Patent Application Publication
(10) Pub. No.: US 2019/0389727 A1
(43) Pub. Date: Dec. 26, 2019

(54) APPARATUS AND METHOD FOR GROWING DISCRETE ULTRALONG CYLINDRICAL SP2 CARBON STRUCTURES

(71) Applicant: The Government of the United States of America, as represented by the Secretary of the Navy, Arlington, VA (US)

(72) Inventors: F. Keith Perkins, Alexandria, VA (US); Ignacio Perez De Leon, Dunkirk, MD (US); Paul M. Campbell, Alexandria, VA (US); Adam L. Friedman, Silver Spring, MD (US); Erin Cleveland, College Park, MD (US)

(21) Appl. No.: 16/448,336

(22) Filed: Jun. 21, 2019

Related U.S. Application Data
(60) Provisional application No. 62/688,411, filed on Jun. 22, 2018.

(51) Int. Cl. C01B 32/16; C23C 16/02; C23C 16/26; C23C 16/56

(52) U.S. Cl. CPC C01B 32/16; C23C 16/0218; B82Y 40/00; C23C 16/56; C23C 16/26

(57) ABSTRACT

A method of forming a carbon microtube includes providing a wire substrate in a heated furnace, contacting a surface of the wire substrate in the heated furnace with a reducing gas, forming a carbon microtube on the wire substrate by chemical vapor deposition of a carbon precursor in the heated furnace, and removing the carbon microtube, on the wire substrate, from the furnace.

This application claims the benefit of U.S. Provisional Application Ser. No. 62/688,411, filed Jun. 22, 2018, entitled “Method of growing discrete ultralong cylindrical sp2 carbon structure,” by F. Keith Perkins, et al., the disclosure of which is incorporated herein by reference in its entirety.

### BACKGROUND

Aspects of the exemplary embodiment relate to a carbon microtube, a method of forming the carbon microtube and to a device incorporating the carbon microtube.

Single-walled, carbon nanotubes (SWCNT) are an allotrope of carbon, which is similar to graphene and buckminsterfullerene in that the carbon bonding arrangement is described as sp², a planar configuration of three hybridized orbitals, giving each atom three nearest neighbors. This leads to an extended hexagonal arrangement of carbon atoms. In the case of carbon nanotubes, this extended arrangement takes the form of a cylinder of defined radius and, in principle, an indefinite length. The angular relationship between the principle axes of the hexagonal network and the cylindrical axis defines the chirality of the nanotube structure, and also defines the electronic structure of the material (metallic or semiconducting). A consequence of the unique electronic structure of these carbon allotropes is that all the electron density (from bonding due to localized orbitals and conductivity due to extended, delocalized charge carriers) is in the monatomic layer, and very little electron density out of the layer.

Methods of producing carbon nanotubes include arc discharge between carbon electrodes (Ando, et al., “Preparation of Carbon Nanotubes by Arc-Discharge Evaporation,” Jpn. J. App. Phys., Vol. 32, Part 2, Number 1A/B, pp. L107-L109 (1993)) and laser ablation of carbon feedstock (Zhang, et al., “Single-wall carbon nanotubes synthesized by laser ablation in a nitrogen atmosphere,” App. Phys. Lett. 73, 3827-3829 (1998)). These methods tend to result in nanotubes with high levels of impurities. Arc discharge produced carbon nanotubes (CNTs) are reported to be 1-2 μm long while those produced by laser ablation are somewhat longer. Chemical vapor deposition from carbon feedstock and a carrier gas in a furnace on catalyst particles floating in vapor has also been used for CNT preparation (Nikolaev, et al., “Gas-phase catalytic growth of single-walled carbon nanotubes from carbon monoxide,” Chem. Phys. Lett., 313 (issues 1-2), pp. 91-97 (1999)). The result was 1-10 micron long CNTs at high yield. Nanotubes have also been formed on substrates (Zhao, et al., “A facile method to align carbon nanotubes on polymeric membrane substrate,” Scientific Reports, volume 3, Article number: 3480 (2013)). This method produced distributed length nanotubes at low yields.

CNT yarns incorporating short length nanotubes have also been produced. In this process, transition metal catalyst particles are aerosolized and dispersed in flowing carrier gas, mixed with a carbon feedstock, and streamed into a furnace. This generates an aerogel “sock” of short (about 1-10 μm) carbon nanotubes, attached to each other by van der Waals forces. The CNT yarn can be condensed, wound, and used for many applications. One problem with such a yarn is that the tensile strength is fairly low, in comparison to the tensile strength of nanotubes. For example, a yarn strength of 8.8 GPa is noted by Koziol, et al. (“High-performance carbon nanotube fiber,” Science, 318 (5858):1892-1895 (2007)). This has been considered to be the strongest CNT yarn by Yadav, et al. (“High Performance Fibers from Carbon Nanotubes: Synthesis, Characterization, and Applications in Composites, A Review,” Ind. Eng. Chem. Res. 56, 12407-12437 (2017)). This is significantly less than that of the discrete CNT, where the measured tensile strength prior to failure of the outermost layer alone of multiwall tubes has been reported as between 11 and 63 GPa, by Yu, et al., “Strength and Breaking Mechanism of Multiwalled Carbon Nanotubes Under Tensile Load,” Science, 287 (5453): 637-640 (2000), and from 63 to 100 GPa by Peng, et al., “Measurements of near-ultimate strength for multiwalled carbon nanotubes and irradiation-induced crosslinking improvements,” Nat. Nanotechnol. 3(10):626-631 (2008).

Rather than strictly tensile failure, the low tensile strength of CNT yarn may be attributable to the poor shear strength of these CNT assemblies, allowing mechanical yield from slippage between adjacent CNTs.

Additionally, the micro architecture of CNT yarns also affects their suitability for electrical conduction applications. The theoretical electrical conductivity of a single nanotube has been estimated as 3.0×10⁸ S/m (Zhang, et al., “Low-temperature resistance of individual single-walled carbon nanotubes: A theoretical estimation,” Appl. Phys. Lett. 79, 3515 (2001). However, the highest value reported for a practical large-diameter (>300 μm) wire formed from densified and acidified CNT paper is 1.3×10⁶ S/m (Alvarenga, et al., “High conductivity carbon nanotube wires from radial densification and ionic doping,” Appl. Phys. Lett. 97, 182106, pp. 1-3 (2010)). Similar to strength limitations, the factor limiting long range transport is the charge carrier mobility barrier of the requisite tube-tube scattering. Yarns also show increased permeability to corrosives, as compared to individual single-walled carbon nanotubes.

Commercially available yarns formed from 1-10 μm nanotubes are sold under the tradename Miralon® by Nanocomp Technologies, Inc.

Copper foil has also been used to grow graphene, planar sheets of sp² hybridized, hexagonal carbon monolayer films. See, for example, Li, et al., “Large-Area Synthesis of High-Quality and Uniform Graphene Films on Copper Foils,” Science, 324, 1312-1314 (2009). However, the resulting carbon structure is two-dimensional, as compared to a three-dimensional tube.

A method for producing high-strength, electrically-conductive carbon microtubes is desired.

### BRIEF DESCRIPTION

In accordance with one aspect of the exemplary embodiment, a method of forming a carbon microtube includes providing a wire substrate in a heated furnace. A surface of the wire substrate in the heated furnace is contacted with a reducing gas. A carbon microtube is formed on the wire substrate by chemical vapor deposition of a carbon precursor in the heated furnace. The carbon microtube is removed from the furnace, e.g., supported on the wire.

In accordance with another aspect of the exemplary embodiment, a carbon microtube assembly includes a core having a length of at least 10 cm. A carbon microtube surrounds the core. The carbon microtube includes at least one layer of predominantly sp² carbon. The at least one layer has an outer diameter of no more than 100 μm.

In accordance with another aspect of the exemplary embodiment, an apparatus for forming a cylindrical carbon structure includes a furnace including a chamber which defines a hot zone. A transport mechanism progressively transports a wire through the hot zone. A source of a reducing gas is connected with the chamber. A source of a carbon precursor is connected with the chamber. The carbon precursor is catalytically converted to a cylindrical carbon structure on the wire.

### BRIEF DESCRIPTION OF THE DRAWINGS

FIG. 1 is a perspective view (not to scale) of an assembly including a carbon microtube supported on a wire, in accordance with one aspect of the exemplary embodiment;

FIG. 2 schematically illustrates a multiwalled microtube;

FIG. 3 is a schematic drawing illustrating a cross-section of the carbon microtube of FIG. 1, in accordance with one aspect of the exemplary embodiment;

FIG. 4 illustrates a cross-section of the carbon microtube of FIG. 1, flattened due to removal of the wire, in accordance with another aspect of the exemplary embodiment;

FIG. 5 illustrates an assembly including carbon microtubes sheathing fine copper wires embedded in a matrix material;

FIG. 6 illustrates a rope or yarn formed from multiple microtubes;

FIG. 7 illustrates a woven fabric formed from multiple microtubes;

FIG. 8 is a schematic, cross-sectional section, of an apparatus for growing carbon microtubes in accordance with another aspect of the exemplary embodiment;

FIG. 9 is a perspective view, in partial section, of the apparatus for growing carbon microtubes of FIG. 8;

FIG. 10 is a perspective view of an apparatus for growing carbon microtubes in accordance with another aspect of the exemplary embodiment;

FIG. 11 illustrates a method for forming a carbon microtube;

FIG. 12 shows a Raman spectrum from a coated copper wire sample showing D and G peaks of roughly similar intensity;

FIG. 13 is an electron micrograph of a carbon microtube formed on copper; and

FIG. 14 is an electron micrograph of a carbon microtube after removal of the supporting nickel wire;

FIG. 15 is an electron micrograph of a lightly-etched carbon microtube formed on nickel; and

FIG. 16 is an electron micrograph of a carbon microtube formed on nickel after removal of the nickel wire.

### DETAILED DESCRIPTION

A method is described which is suited to growing discrete (untangled) carbon microtubes (CMTs) and larger cylindrical structures. The CMTs can be virtually infinitely long and may be embedded in a polymer or metal matrix.

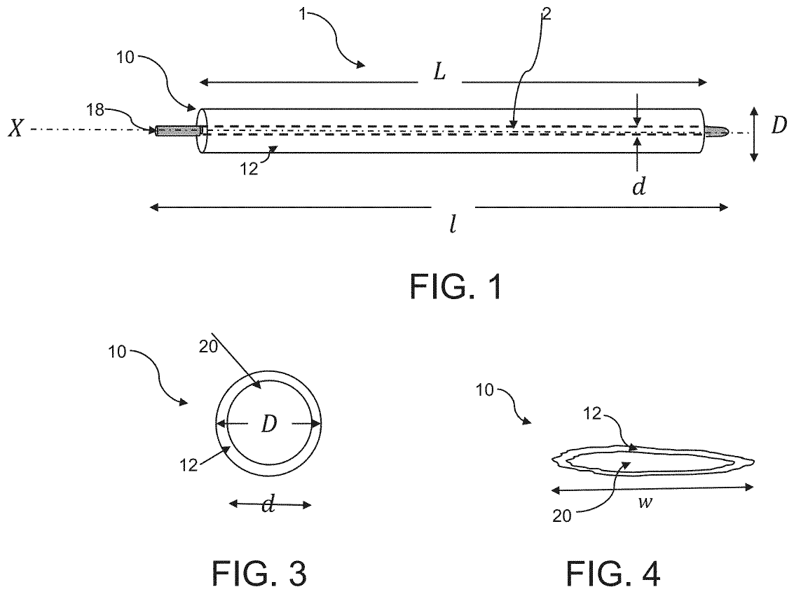

An exemplary assembly 1 including a core 2 and a carbon microtube (CMT) 10 is illustrated schematically in FIG. 1. The microtube surrounds the core. The microtube has an sp² carbon structure (graphene). The carbon microtube 10 is predominantly sp² carbon. For example, the carbon microtube 10 may be at least 50 wt. % sp² carbon, or at least 70 wt. % sp² carbon, or at least 90 wt. % sp² carbon, or at least 95 wt. % sp² carbon, or at least 99 wt. % sp² carbon, or up to 100 wt. % sp² carbon. Raman spectroscopy of microtubes suggests that very close to 100 wt. % sp² carbon can be readily achieved. The microtube 10 is cylindrical or a flattened cylinder, i.e., it has a continuous surface perpendicular to its longitudinal axis X and a core of a different material (air and/or solid material).

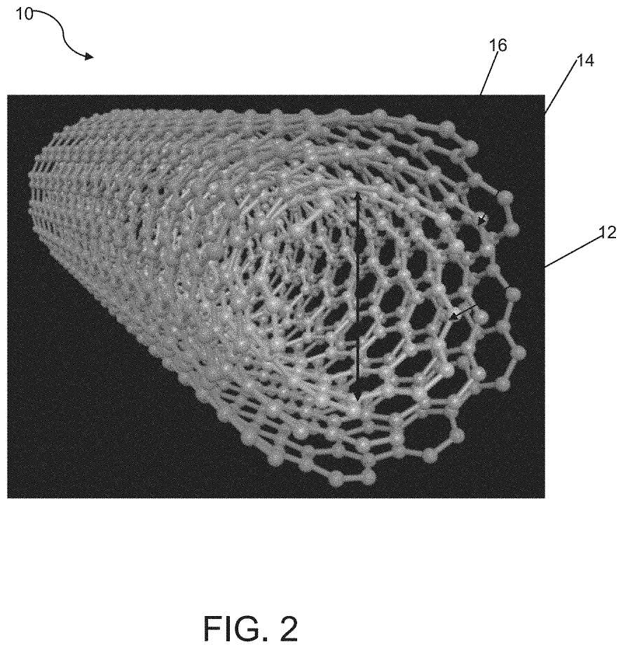

The microtube 10 may be a single-walled structure, i.e., include a single wall 12 composed of a monolayer of sp² carbon (a cylindrical hexagonal honeycomb lattice) having a radius of curvature. In other embodiments, the microtube 10 may be multi-walled structure as illustrated in FIG. 2. The multi-walled microtube is composed of two or more concentric layers 12, 14, 16, etc. of sp² carbon. Each layer may be configured as for a single-walled microtube. The separate layers 12, 14, 16 are held together by van der Waals forces. While FIG. 2 shows three layers, the number of layers is not limited and may be, for example, at least two, or at least three or at least four, or at least five, such as up to twenty, or up to fifteen, such as about 10.

In the embodiment of FIG. 1, the single-walled microtube 10 may have an outer diameter (or mean outer diameter) D of no more than 100 microns (μm), e.g., up to 50 microns, or up to 20 microns, or up to 12 microns in diameter D. The outer diameter D may be at least 0.01 micron, or at least 0.1 micron, or at least 1 micron, or at least 5 microns. As an example, a single-walled microtube may have a diameter of 5-15 μm. However, it is to be appreciated that larger diameter tubes, such as up to 1 mm, or more, may be formed with the methods described herein. In some embodiments, the assembly 1 has a taper along its length, in which case, D represents the minimum outer diameter. For a multi-walled microtube as shown in FIG. 2, one or more of the outer layers 14, 16, etc., may have a larger diameter D than that exemplified for a single-walled microtube.

The microtube 10 shown in FIG. 1 has a length L which exceeds the diameter D, e.g., L≥5×D, or L≥10×D, or L≥20×D, or L≥100×D, or L≥1000×D. The length L of the microtube may be at least 50 μm, such as at least 100 μm, or at least 1 mm, or at least 5 mm, or at least 1 cm, or at least 2 cm, or at least 10 cm, or at least 20 cm, or at least 60 cm, and in some embodiments, up to 100 cm, or more.

As will be appreciated cylindrical structures of larger cross-section than the exemplary microtubes are also contemplated, e.g., up to 1 mm, or up to 1 cm in diameter, or more.

As illustrated in FIG. 1, the exemplary single-walled (or multi-walled) CMT 10 may be supported on an elongated substrate 18, in the form of a wire, which defines the core 2. The wire 18 can be formed from a solid core of catalytic metal or a catalytic metal coating some other suitable material. For example, a catalytic metal may coat an insulator, such as glass or a ceramic, or may coat a non-catalytic metal, such as titanium.

The catalytic material of the wire serves as a catalyst for chemical vapor deposition of the microtube 10, during its formation. The wire 18 may be formed solely of the catalytic metal(s) (e.g., at least 90% pure metal). In another embodiment, the catalytic metal may form an outer coating on an inner core of a different material. Example catalytic metals include copper (Cu), nickel (Ni), platinum (Pt), other transition metals (e.g., other Pt group transition metals, such as Hf, Ta, W, Re, Os, Ir, and Au), vanadium (V). iron (Fe), and others of the 3d transition metals, alloys thereof (e.g., Ni/Fe), and compounds thereof, such as platinum carbide. In one exemplary embodiment, the metal is Cu or nickel and uniform in composition and diameter. In another other embodiment, a multilayer metal wire substrate 18 may be used. Such a wire may be fabricated by, for example, electroplating copper onto another metal selected for other properties. The wire may be of a uniform cylindrical diameter along its length or tapered along its length. The imposition of a taper, e.g., by forming a thick deposition of a catalyst metal onto a finer metal (that is known not to efficiently catalyze carbon growth, e.g. stainless steel), can be used to grow and handle a single microtube that can be more easily detached intact from the metallic substrate.

The wire 18 has a length l, which may be ≥L. The wire is generally cylindrical in cross section. The wire 18 has a diameter (or mean diameter) d<D, e.g., of up to 40 μm, or up to 20 μm, such as at least 1 μm, or at least 5 μm diameter. d corresponds to the inner diameter of the CMT 10. In the case where the wire has a taper along its length l, d may represent the minimum diameter of the wire 18. The length L of the microtube 10 can be predetermined, e.g., by selecting the length of wire to be passed through, or otherwise exposed within, the forming apparatus. The wire 18 may have a substantially circular or circular (round) cross section, e.g., a ratio of maximum diameter to minimum diameter at any given point of up to 3:1 or up to 2:1 or about 1:1. In the following, it is assumed that both the wire and the microtube are circular in cross section.

The wire 18 may be partly or completely removed from the microtube assembly 1, to provide a microtube 10 with a wall 12 (or multiple layers in the case of the microtube of FIG. 2) which defines a hollow cavity 20, of diameter d, as illustrated in FIG. 3. In the case where the wire has a taper, d may represent the minimum diameter of the cylindrical cavity 20. In some embodiments, the wall 12 may be at least partially collapsed and the microtube is no longer hollow, e.g., the microtube is a ribbon, or is substantially flattened, as illustrated in FIG. 4. The ribbon has a width w=˜π×D/2, if flat, where D is the diameter of the assembly. For an assembly/wire with a diameter of about 10 μm, w may thus be about 15 μm.

The thickness t of the single wall 12 (2t=D−d) is approximately that of a monolayer of sp² carbon (˜0.3 nm). In practice, discontinuities or stitching errors in the purely hexagonal sp² lattice structure may occur, due to initiation of the formation of the cylindrical microtube 10 at different points on the wire 18. However, as a whole, the wall 12 is able to provide structural strength, corrosion resistance, electrical conductivity, and/or other properties suited to the applications described herein.

The exemplary microtube 10 may be used in a variety of applications. For example, it may be used to increase tensile strength of high-conductivity copper wire, to increase conductivity of high strength steel or ceramic microfibers, to inhibit corrosion of steel, copper, or some other wire 18 by the atmosphere and/or by materials in which the microtube 10 is embedded, and/or as a reinforcement in polymer matrix composite materials, e.g., carbon fiber epoxy laminates.

In one embodiment, the CMT 10 may serve as a sheathing for the wire 18, e.g., to provide corrosion protection for one or more fine copper wires 18, as illustrated, for example, in FIG. 1. The CMT may thus provide corrosion resistant sheathing on fine wires 18 exposed to corrosive environments, such as sea water or strong acids or bases. For example, the assembly 1 may be formed by direct processing of Cu or Ni wires, or by first cladding other wire stock with a transition metal catalyst.

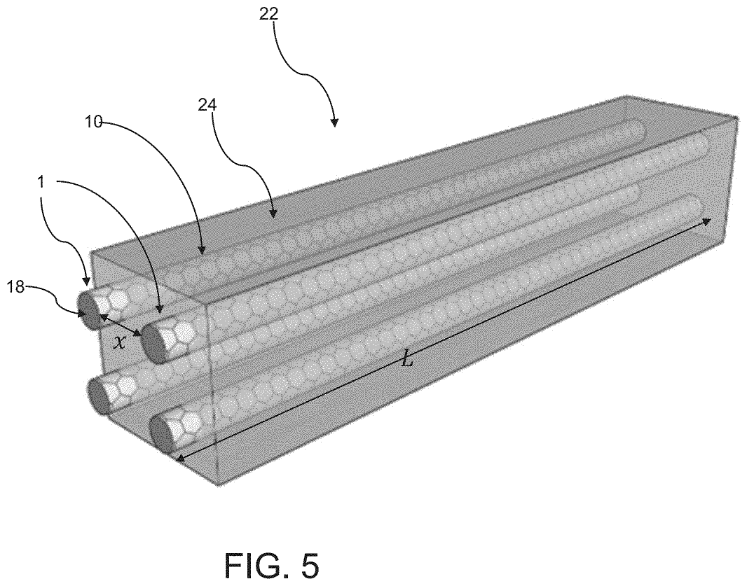

In another embodiment, the CMT 10 or CMT assembly 1 is embedded in a surrounding material, which is different from the material of the wire 18 and CMT 10. For, example, as illustrated in FIG. 5, an assembly 22 may include one or more CMTs 10 (optionally carried on respective wires 18), embedded in a surrounding matrix 24. In the case of multiple CMTs 10, as illustrated in FIG. 5, the CMTs may be arranged generally in parallel and spaced from each other by the matrix material 24. While the illustrated assembly 22 includes four microtubes, fewer or more than four are contemplated, such as 1, 2, 3, or at least 5, at least 6, at least 8, at least 10, at least 20, or more microtubes, e.g., arranged in an array. A minimum distance x between microtubes may be at least ¼ D. However, other regular or more random arrangements of microtubes are contemplated.

Example matrix materials include polymers and metals. For example, the matrix material 24 may include, but is not limited to, any of various epoxies, thermoset plastics, phenolic plastics, steels, and aluminum.

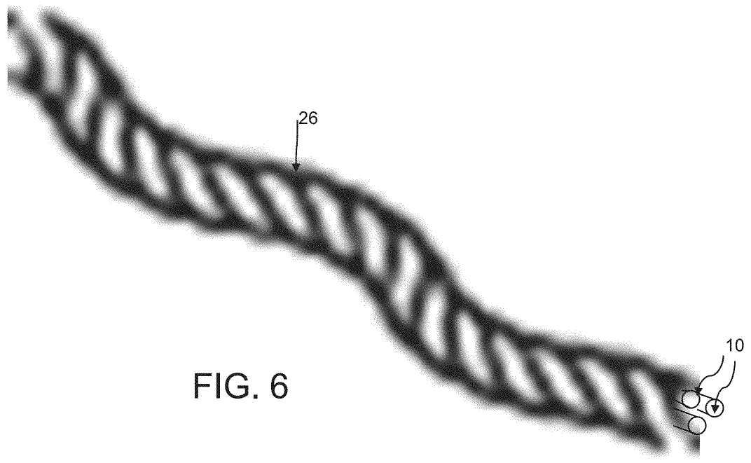

In another embodiment, a rope 26 is formed of multiple CMTs 10 or CMT assemblies 1, as illustrated, for example, in FIG. 6. The rope 26 may be formed by twisting together strands composed of CMTs 10 or CMT assemblies 1. In this embodiment, the CMTs 10 or CMT assemblies 1 may be in contact with each other. Optionally, the CMTs/assemblies are coated with a protective (e.g., polymer) coating, before or after twisting together to form the rope.

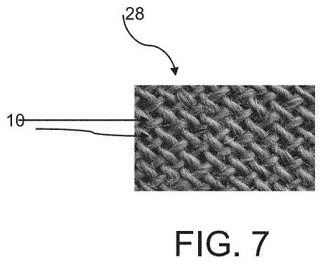

In another embodiment, a fabric 28, such as a woven or non-woven fabric, is formed from multiple CMTs 10 or CMT assemblies 1, as illustrated, for example, in FIG. 7. In this embodiment, the CMTs 10 or CMT assemblies 1 may be in contact with each other. Optionally, the CMTs/assemblies are coated with a protective (e.g., polymer) coating, before or after weaving/matting them together to form the fabric.

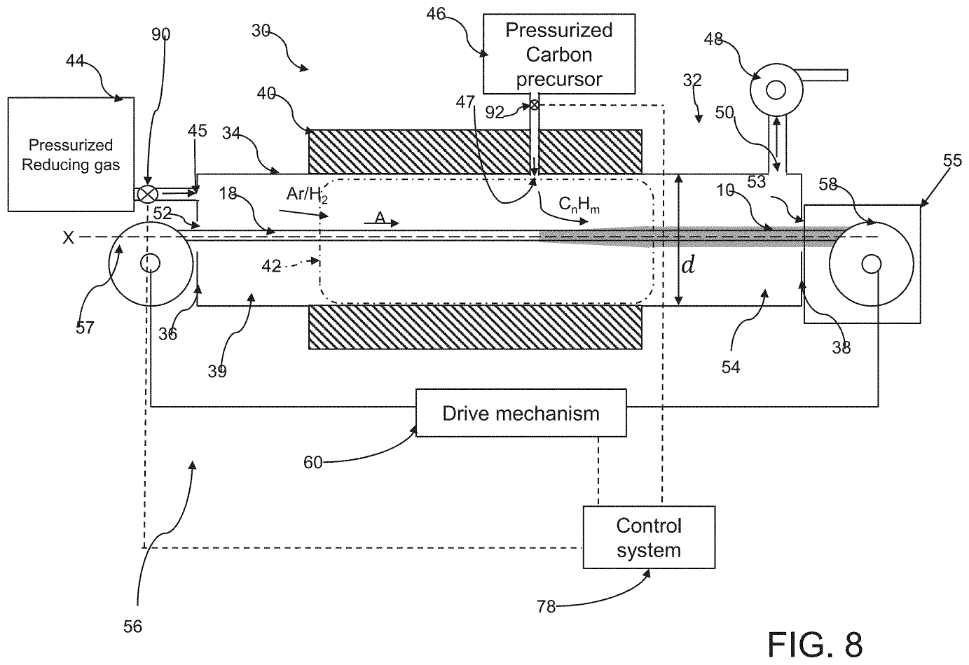

With reference to FIG. 8, an apparatus 30 for forming discrete carbon microtubes 10 of indefinite length is shown. The apparatus 30 includes a high temperature refractory furnace 32. The furnace includes a linear tube 34 of diameter d>D, with spaced first and second substantially closed ends 36, 38, which together define an interior chamber 39. The tube 34 is formed from quartz or other refractory material. The apparatus also includes a heater 40, external to the tube 34, which provides a hot zone 42 (hottest part of the furnace) within the tube 34.

A first gas source 44 provides a reducing gas to a first inlet 45 to the interior chamber 39, which is located at or adjacent the first end 36 of the tube 34. The reducing gas may be introduced at a slight positive pressure, as compared to the pressure outside the tube, so that it flows downstream in the direction of arrow A to outlet 50, at a lower pressure than at inlet 45. The reducing gas removes impurities from the surface of the wire, e.g., by reduction of metal oxides in the hot zone. For example, the reducing gas includes hydrogen, which is optionally mixed with an inert diluent gas, such as argon, neon, or helium. In one embodiment, a ratio of moles hydrogen (H₂) to moles inert gas (e.g., Ar) in the reducing gas is at least 1:10, such as at least 1:5, or at least 1:3, or up to 2:1, or up to 1:2. In particular embodiments, the ratio of moles hydrogen (H₂) to moles inert gas (e.g., Ar) in the reducing gas is 2:3. The inert gas and hydrogen may be provided from a single gas cylinder 44 or from respective gas cylinders. In addition to reducing impurities on the wire surface, the hydrogen gas also serves to mop up excess oxygen gas which may enter the furnace. While a small amount of oxygen may not be detrimental, larger amounts may interfere with the process.

A second gas source 46 provides a precursor gas to a second inlet 47, downstream of the first inlet 45, e.g., within the hot zone 42 of the tube 34. The precursor gas may be introduced at the same or a slight positive pressure, as compared with the pressure in the tube, so that the precursor gas is predominantly carried downstream, in the direction of arrow A, to outlet 50, rather than upstream. The precursor gas includes a gaseous carbon precursor, which can be decomposed to form sp² carbon in the hot zone of the furnace via catalysis on the surface of the metal substrate 18. An exemplary carbon precursor may include one or more C₁-C₁₀ hydrocarbons (generally represented by the formula CₙHₘ, where n≤m, in particular, m≤2n+2, and n is at least 1 and no more than 10, such as no more than 6, or no more than 4). As used herein, a hydrocarbon is composed solely of the elements hydrogen and carbon. The hydrocarbon may be a C₁-C₁₀ alkane, alkene, or aromatic hydrocarbon molecule, or mixture thereof, such as methane (CH₄), ethene (C₂H₄), ethane (C₂H₆), propylene (C₃H₆), benzene (C₆H₆), combinations thereof, and the like. C₁-C₁₀ alcohol equivalents of such hydrocarbons (generally represented by the formula CₙHₘOₚ, where m≥n, and n is at least 1 and no more than 10, such as no more than 6, and m, n, and p are each at least 1), such as methanol, ethanol, propan-1-ol, propan-2-ol) may alternatively or additionally be employed as gaseous carbon precursor(s). C₁-C₃ alkanes and alkenes are particularly suitable. The precursor gas may further include a diluent gas, such as argon, or other inert gas.

In one embodiment, a ratio of rate of hydrogen introduction to the chamber, in moles/min, to rate of carbon introduction, in moles/min, is at least 2:1, or at least 5:1 or at least 10:1, or at least 50:1, or at least 100:1, or at least 5000:1, and may be up to 10,000:1, or up to 1000:1. In particular embodiments, the ratio of rate of hydrogen introduction to the chamber, in moles/min, to rate of carbon introduction, in moles/min, is about 80:1.

The hot zone 42 has a temperature, adjacent the wire 18, which is generally below the melting point of the wire. For example, in the case of wire 18 that is formed from or includes copper, the hot zone 42 may have a temperature of less than 1080° C. (the melting point of copper being 1083° C.). For example, the hot zone may have a temperature of at least 850° C., or at least 900° C., or at least 1000° C., such as up to 1060° C., or about 1030° C. For wires formed predominantly of higher melting materials, the hot zone may have a higher temperature. For example, in the case of nickel wire, which has a melting point of 1455° C., the hot zone temperature may be, for example, up to 1450° C., such as up to 1420° C.

Residual gas (e.g., a mixture of hydrogen, carbon precursor, atomic carbon, any diluent gases, water produced in the reduction process, sublimated metal from the wire) is released from (or pumped by a pump 48) from an outlet 50, at or adjacent the second end 38 of the tube 34. As will be appreciated, the gas flow is generally from left to right (upstream to downstream) in FIG. 4, although other embodiments are contemplated.

Small openings 52, 53 in the first and second ends 36, 38 allow the wire 18 to pass through the tube 34, substantially along a central axis X of the tube, in the direction of arrow A, which is generally aligned with the direction of gas flow. The wire 18 is drawn through the tube at a suitable rate for pretreatment and carbon deposition to occur in the hot zone, which may depend on the hot zone temperature, length of the hot zone, wire material (e.g., copper vs nickel), and the like. In the hot zone 42, the wire surface is first reduced from metal oxide to metal, by a reducing gas, and the metal is then annealed, reducing the number of crystallographic defects. Sublimation of some of the metal from the wire may also occur, reducing its thickness. Then, as the wire reaches the second inlet 47, chemical vapor deposition of carbon occurs through the catalytic decomposition of the carbon precursor(s). The wire 18 serves as a mold, scaffold, or substrate for the catalytic decomposition. A cooler region 54 of the tube 34, downstream of the hot zone 42, allows the coated wire 18 to cool and allow carbon to deposit on the surface of the wire in a substantially oxygen-free atmosphere before leaving the furnace. In one embodiment, the wire may exit the furnace into a cooling container 55 which is slightly pressurized with helium and optionally hydrogen, until reaching a suitable temperature, such as below about 200° C., or 150° C., before exposure to the ambient atmosphere.

The rate of oxidation of impurities, sublimation of the wire metal, and deposition of sp² carbon are dependent, in part, on the hot zone temperature and its length. Lower/higher flow rates of the gases may be used to achieve optimal/desirable reduction and/or sublimation rates and/or sp² carbon deposition rate. Alternatively, or additionally, a rate of transfer of the wire (in mm/min) through the furnace may be adjusted to achieve such optimal/desired results. In the case of nickel wire, a multi-layer carbon microtube can be formed. Accordingly, the furnace parameters (e.g., one or more of gas flow rates in moles/min, wire transfer rate, hot zone temperature, length of hot zone) may be selected/adjusted to achieve the desired wire thickness and/or number of layers 12, 14, 16, etc. in the microtube.

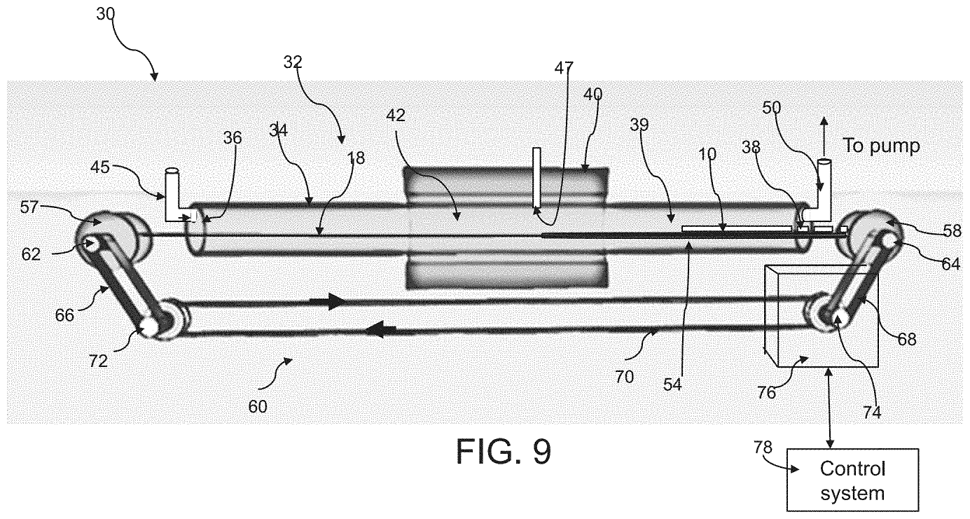

The wire 18 is carried though the quartz tube by a transport mechanism 56. The illustrated transport mechanism 56 includes a feed reel 57, which is positioned on one side of the hot zone 42, e.g., adjacent the first end 36 of the furnace tube, and a take-up reel 58, which is positioned on an opposite side of the hot zone 42, e.g., adjacent the second end 38. The wire 18 is progressively transferred from the feed reel, through the chamber, and on to the take-up reel. The reels 57, 58 are synchronized to keep the wire under a very slight tension as it passes through the furnace, in order to keep it relatively straight, but not taut to the extent that the wire or microtube could fracture. In one embodiment, the reels 57, 58 are driven by a common drive mechanism 60, as illustrated, for example, in FIG. 9. In the illustrated embodiment, each reel 57, 58 has an axial shaft 62, 64, which carries a respective driven belt 66, 68. The belts 66, 68 are driven by a common drive belt 70. The motion of the drive belt is transferred to one or both driven belts 66, 68 through respective drive shafts 72, 74. One or both of the drive shafts 74 is driven at a constant speed by a suitable drive motor 76. As will be appreciated, other drive mechanisms are also contemplated.

The length of the CMT 10 formed in the apparatus 30 is limited only by the amount of wire 18 provided on the feed reel 57 that passed through the furnace. The wire with the microtube attached is sufficiently flexible that it remains intact, even when wound onto the take-up reel 58. In one embodiment, a terminal end of the wire may be attached to the feed reel, causing the motor to stop automatically once an increased tension is detected. In one embodiment, the motor 76 may be under the control of a control system 78 which may cause the motor to start the rotation of the reels to provide a preselected wire transfer speed when the furnace is at temperature and the gases are flowing and then pause the reels when a preselected length of wire has been coated with a CMT, or when the wire has been used up, or at another preselected time. The control system 78 may also control other parameters of the furnace, such as gas flow rates (through control of valves 90, 92), furnace temperature (through control of heater 40), and the like.

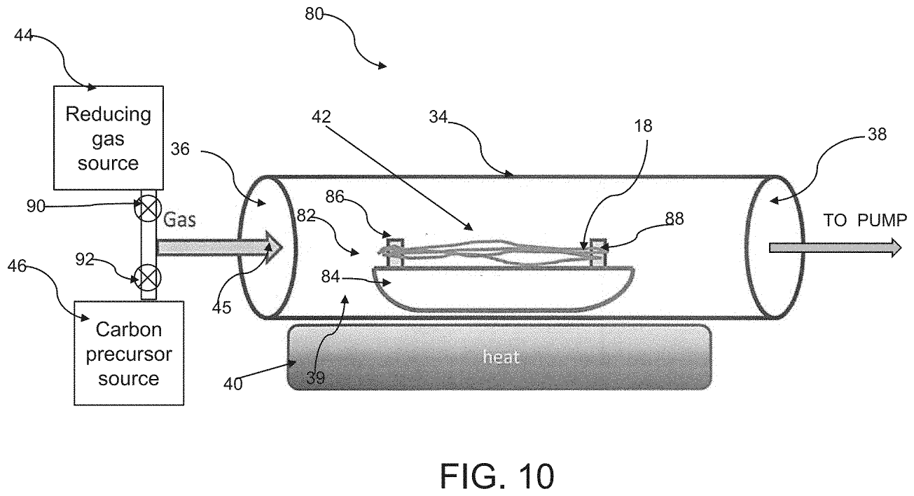

With reference now to FIG. 10, another embodiment of an apparatus 80 for forming discrete carbon microtubes 10 is shown. The apparatus 80 can be configured similarly to the apparatus 30 of FIGS. 4 and 5, except as noted. In this embodiment, the wire 18 is not carried through the tube 34, but is held in a stationary position by a suitable support device 82 in a furnace (e.g., a clamshell-type furnace). The illustrated support device includes a base 84, such as a boat, which supports two (or more) vertically-extending rods 86, 88. The rods are spaced along the length of the tube 34. The wire 18 is wrapped around the spaced rods. The base 84 and rods 86, 88 are formed from a suitable refractory material, such as alumina (Al₂O₃) for the base and fused silica (SiO₂) for the rods. The length of the CMT 10 formed in the apparatus 80 is limited to the length of wire 18 provided in the furnace.

In this embodiment, the reduction and precursor gases may be introduced through a common inlet 45, e.g., by selectively opening and closing valves 90, 92 to allow first the reducing gas and then the precursor gas to enter the chamber 39 for predetermined time periods. For example, the reducing gas is introduced first, then subsequently the precursor gas is introduced while a flow of reducing gas is optionally maintained. Alternatively, the reducing gas and precursor gas may be provided through separate inlets.

The metal wire 18 can be removed from the finished microtube 10 or allowed to remain within the microtube.

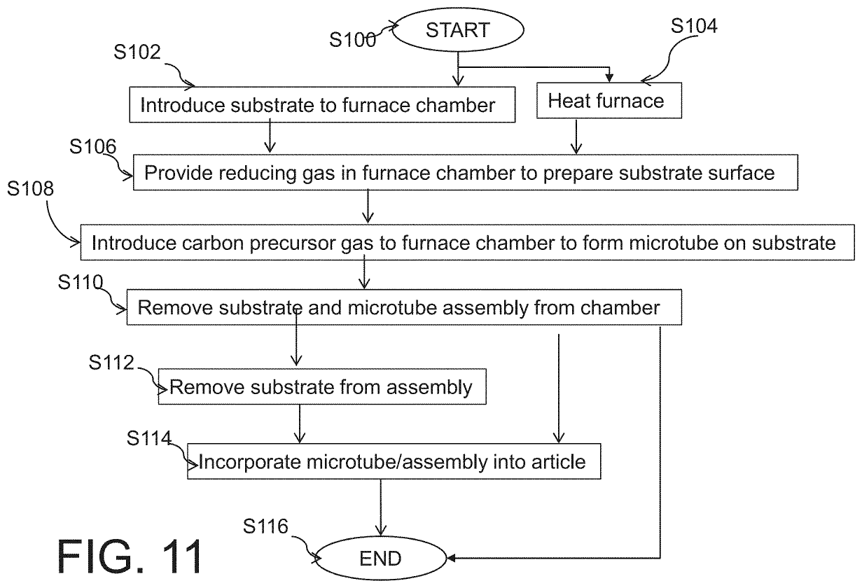

With reference to FIG. 11, a method for forming ultra-long carbon microtubes (CMT) is illustrated. The method may be performed in the apparatus of FIGS. 8-9 or FIG. 10. The method begins at S100.

At S102, a substrate in the form of a fine wire 18 (e.g., 10-40 μm diameter Cu or Ni) is introduced to a furnace chamber 39. In the embodiment of FIGS. 8-9, the method is implemented as a Reel-to-Reel (R2R) process with synchronized feed and take-up reels 57, 58 drawing wire through the hot zone 42 of the fused silica tube furnace. In this embodiment, the wire is mounted on the reels 57, 58 and only a portion of the wire 18 is in the chamber at any time. In the static embodiment of FIG. 10, the entire wire 18 is suspended on the support 82 and positioned in the chamber 39. The wire 18 may have a useable length (length to be surrounded by the microtube) of at least 10 cm, or at least 50 cm.

At S104, the furnace is heated by the heater 40 to provide a hot zone 42 in the chamber with a suitable temperature for surface preparation of the wire and chemical vapor deposition of carbon. A suitable temperature is generally above the forging temperature of the wire. In an exemplary embodiment, the furnace is heated to 1030° C. The furnace may be at least partially heated to the operating temperature prior to introduction of the wire, e.g., in the embodiment of FIGS. 8-9, or heated after introduction of the wire, e.g., in the embodiment of FIG. 10.

At S106, a reducing gas, such as an atmosphere of H₂ in an inert diluent gas, such as Ar, is provided in the chamber 39 to contact the heated wire 18. The reducing gas removes oxides and impurities from the surface of the wire and promotes growth of crystalline domains. In the embodiment of FIGS. 8-9, this may include opening the valve 90 to allow reducing gas to continuously flow through the first inlet 45, into the chamber and out of the outlet 50. In the embodiment of FIG. 10, this may include opening the valve 90 to allow reducing gas to enter the chamber 39 through the common inlet 45. The valve 90 may be closed after a predetermined time period. Since the wire thins due to sublimation and oxidation, a suitable annealing time is selected (e.g., 5 mins or less prior to introduction of the precursor) to remove oxide and impurities, without undue loss of metal.

At S108, a carbon precursor gas, such as CH₄ or C₂H₄, is introduced to the chamber 39, where it undergoes catalytic decomposition at the surface of the transition metal wire 18. A carbon microtube forms by chemical vapor deposition. In the embodiment of FIGS. 8-9, this may include opening the valve 92 to allow precursor gas to continuously flow through the second inlet 47, into the chamber, and out of the outlet 50, contemporaneously with the flow of the reducing gas (or a portion thereof). In the embodiment of FIG. 10, this may include opening the valve 92 to allow precursor gas to enter the chamber 39 through the common inlet 45, at some time after the valve 90 has been opened (e.g., after at least 30 seconds or after at least a minute, depending on the furnace temperature). The valve 92 may be closed after a predetermined time period. The valve 90 may remain open while the precursor gas is flowing through the chamber or may be closed for at least part or all the time the precursor gas is flowing. The assembly 1 may be allowed to cool in a reducing (e.g., hydrogen/helium) atmosphere.

At S110, the coated wire assembly 1 is removed from the chamber 39. In the embodiment of FIGS. 8-9, this may include drawing the coated wire through the opening 54 onto the take-up reel 58. In the embodiment of FIG. 10, this may include opening the chamber and removing the boat 84 on which the coated wire is suspended.

At S112, the wire 18 may be removed from the assembly 1, to leave an intact microtube 10. The wire may be removed by etching to remove the Cu or Ni metal core 2 to produce free-standing CMTs. For example, the assembly may be soaked in an ammonium persulfate solution for sufficient time to remove the copper or nickel wire at a temperature of 20-80° C. (e.g., 30-40° C.). Ammonium persulfate in water solution is available, for example, as Transene™ Copper Etchant Type APS-100 (or CE-100) (contains 15-20% ammonium persulfate and water). The time taken depends on the length of the wire. At 20° C., copper may etch at a rate of approximately 0.006 mm/min, using Transene™ Copper Etchant Type APS-100, although the timing is not exact. Slight agitation and/or higher temperature may be used to increase the rate. For example, at 40° C., the etch rate of APS-100 increases to about 0.025 mm/min. After etching, the microtube 10 may be washed in deionized water. Other suitable etchants for copper include ferric chloride solution, available, for example, from Sigma-Aldrich.

If the wire core 2 is removed from the graphitic/metal coaxial assembly, a lightweight material is obtained that is both high strength and highly conductive. This material tends to be collapsible from the as-grown diameter to a nearly flat ribbon of width w=˜3.14×D/2, where D is the wire diameter. The ribbon provides a dense, strong, and lightweight material.

At S114, the assembly 1, or microtube 10, may be formed into an article, such as the assembly 22 of FIG. 5, the rope 26 of FIG. 6, or fabric 28 of FIG. 7. The assembly/microtube(s) may be cut to a uniform/desired length prior to or after assembly into the article.

The method ends at S116.

Specific aspects will now be described.

The very low solubility of carbon in copper around 1030° C. results in the formation of a continuous, high-quality, self-limiting monolayer of graphene enclosing the wire 18 and forming a carbon microtube 10. The higher solubility of carbon in nickel leads to multilayers (multiwall microtubes) grown on the Ni wire.

In the embodiment of FIGS. 8-9, the overgrowth of a carbon microtube jacket adds tensile strength to ultra-fine Cu wire as it sublimates and softens above its forging temperature during CVD processing to enable pulling for the reel-to-reel (R2R) embodiment.

The discrete CMTs 10 formed in the exemplary method can have a tensile strength which is at least five times, or about ten times that of conventional carbon nanotube yarns. The tensile strength of one long tube is significantly greater than the shear strength among many shorter tubes.

It is to be noted that the solubility of carbon in copper at elevated temperatures is relatively poor and falls steeply with temperatures in the vicinity of 1000° C., where catalytic decomposition of methane readily occurs. Thus, by heating Cu to about 1000° C. in an atmosphere of CH₄, H₂ and Ar, a high quality monolayer film of graphene can be synthesized.

Advantages of the microtube, system and method may include:

1. Arbitrarily long discrete microtubes can be formed, particularly when using a reel-to-reel apparatus. Carbon microtubes (tubular graphene) wires can be fabricated with a length considerably greater than can be currently achieved by other methods.

2. Low weight/unit length as compared to CNT yarns of comparable strength.

3. Higher tensile strength than CNT Yarns (e.g., about 10× higher). The tensile strength of one long tube is significantly greater than the shear strength among many short tubes.

4. Adding the carbon microtube provides higher tensile strength than the ultra-fine Cu wire alone.

5. Ultra-strong carbon fibers can be made by winding the CMTs together for forming ultra-strong and light fabrics, ropes, and other structures.

6. The carbon microtube can provide a high electrical conductivity sheathing on fine wires of low electrical conductivity metals such as steel, or on insulators such as glass or ceramics.

7. The carbon microtube can provide a corrosion resistant sheathing on fine wires exposed to corrosive environments, such as sea water, or strong acids or bases, either through direct processing of Cu or Ni wires, or by first cladding other wire-stock with a transition metal catalyst. The carbon microtube can provide corrosion resistance in harsh conditions where polymer coatings are unable to be used or which provide insufficient protection.

8. The fine wire can serve as both a catalyst and scaffold for the growth of CMTs by chemical vapor deposition.

9. The metal core can be removed with a suitable etchant to leave a freestanding carbon microtube.

10. The ability to select microtube wall thickness through the choice of substrate. Cu wire can be used for single layer graphene. Ni wire can be used to grow multiwall CMTs, which is better suited to high strength applications.

11. The sp² carbon film is suited to use in high service temperatures.

12. The carbon microtubes can be used as electrical conductors, independently of the wire.

13. The microtubes 10/assemblies 1 are readily embedded in cast polymer structures, to form a polymer/microtube composite material, which allows realization of hybrid structures with the ease of forming and assembly of the cast polymer combined with some of the tensile strength of carbon microtubes.

Global demand for carbon fiber market is expected to grow, particularly in aircraft and aerospace, wind energy, and the automotive industry, where it may be employed with optimized resin systems. These applications can make use of the various properties of the carbon microtubes described herein. For example, the microtubes can be used to increase the strength/weight ratio of airframes and airfoils (wing structures and skins) for airplanes, by embedding the microtubes in metallic or composite materials, with or without the substrate. Information communicated by the microtubes (e.g., RF signals) can be used to identify and locate cracks otherwise invisible in the structure. Small autonomous vehicles, such as drones, may also benefit from light weight, strong, electrically conducting microtubes/assemblies. The assembly finds use in electrically conducting wires for radar systems.

Without intending to limit the scope of the exemplary embodiment, the following examples illustrate formation of carbon microtubes.

### EXAMPLES

### Example 1

A clamshell-type furnace with a 22 mm inner diameter fused silica tube configured as shown in FIG. 10 is employed to demonstrate the applicability of the method. Ultrafine Cu wire with a diameter of 10 μm is obtained. A length of such wire (about 10 cm long) is looped around a quartz frame on an alumina boat and placed in the hot zone region of the quartz tube furnace. A flowing atmosphere of 40% H₂ and 60% Ar at 1 liter/min (corresponding to about 260 cm/min) is passed through the tube to purge oxygen from the tube prior to heating. The tube is then heated to provide a 1030° C. hot zone. Under such conditions, metal oxide is reduced to pure metal in a few minutes while annealing any damage formed during the drawing process. This competes against sublimation of metal at this temperature, diminishing the diameter. For example, the diameter of the wire is reduced to about 8 μm after heating to the target temperature at approximately 50° C./min and holding for 5 minutes. After 5 minutes at the target temperature, C₂H₄, flowing at 5 ml/min is added to the Ar/H₂ mixture. This causes the accumulation of a thin carbon layer on the surface of the wire, and crystallization into the sp² carbon lattice. After 3 minutes, the carbon source is switched off, and the furnace is opened, switching off the heat and allowing the assembly to cool rapidly while the Ar/H₂ mixture continues to flow. Once the temperature drops below 150° C., the system is opened and the wire assembly removed.

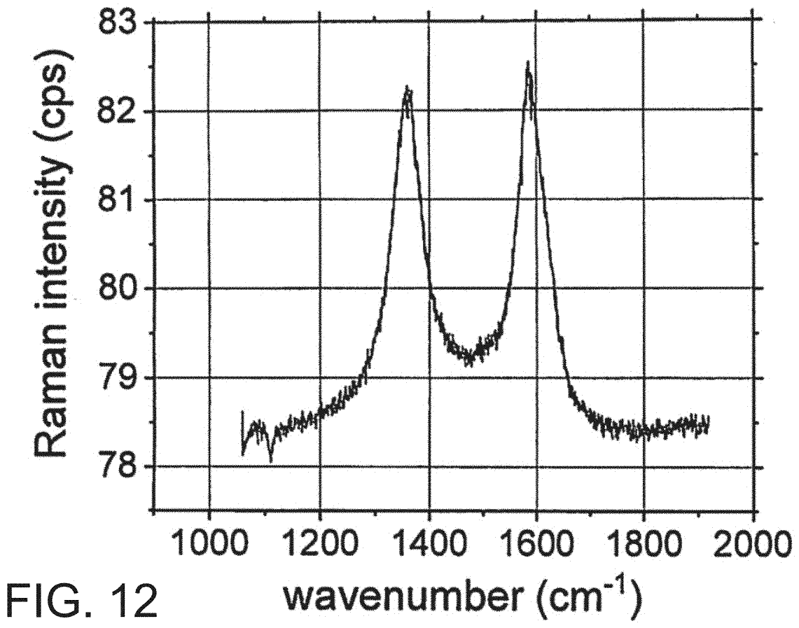

After growth, the coated wire 1 is characterized by Raman spectroscopy to establish that an sp² carbon lattice is formed on the wire (see FIG. 12). D and G peaks are evident from characterization in Raman spectroscopy. This suggests a moderately defective, but nevertheless sp² carbon-derived and continuous, structure.

To test the tensile strength of the assembly 1, one end of the coated wire is attached to a glass slide using adhesive tape while the other end is loaded with paper clips (the first being attached to the wire with adhesive tape) until the wire fails. The total weight of the supported paperclips and tape is 3.2 g. When imaged in an SEM, the diameter remote from the point of failure is 8 μm. This final diameter is not inconsistent with a value expected from mass loss due to sublimation during the metal reduction step. A simple calculation shows the stress withstood prior to failure to be 620 MPa. Compared with the copper wire itself measured prior to thermal processing, the assembly 1 has about 2.5× the tensile strength, as determined by comparing the mass burden at failure for the Cu wire with and without the CMT sheath. Similar thermal processing of Cu wire without the carbon feedstock leaves the wire too brittle to handle.

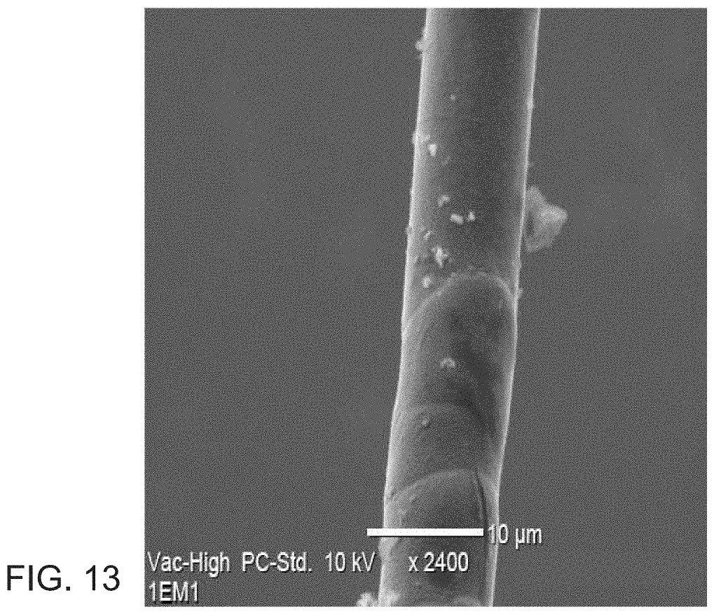

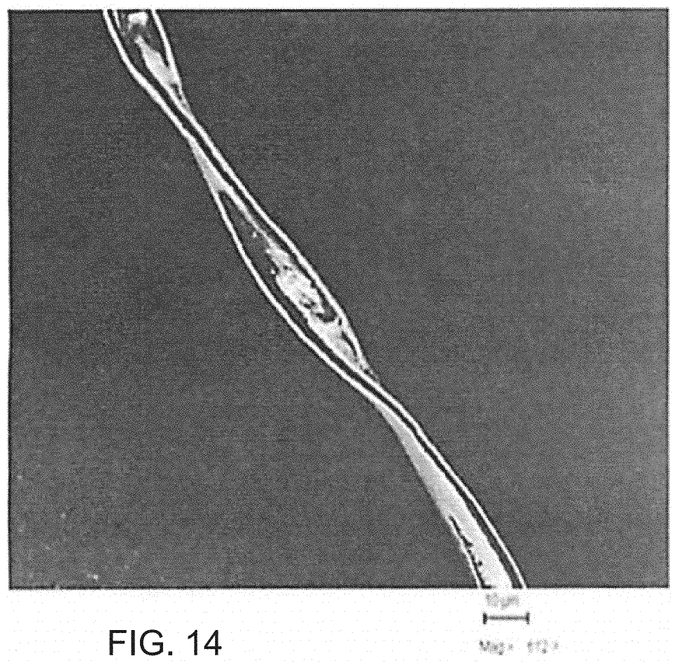

FIG. 13 shows an electron micrograph of the wire.

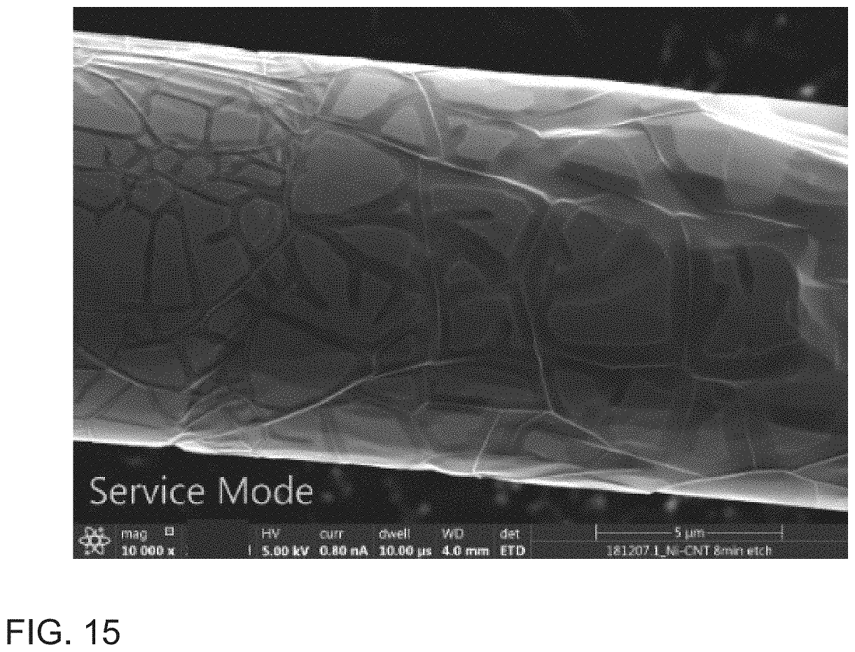

A remaining portion of the wire is etched with Transene™ Cu etch. FIG. 14 is an electron micrograph of the resulting microtube.

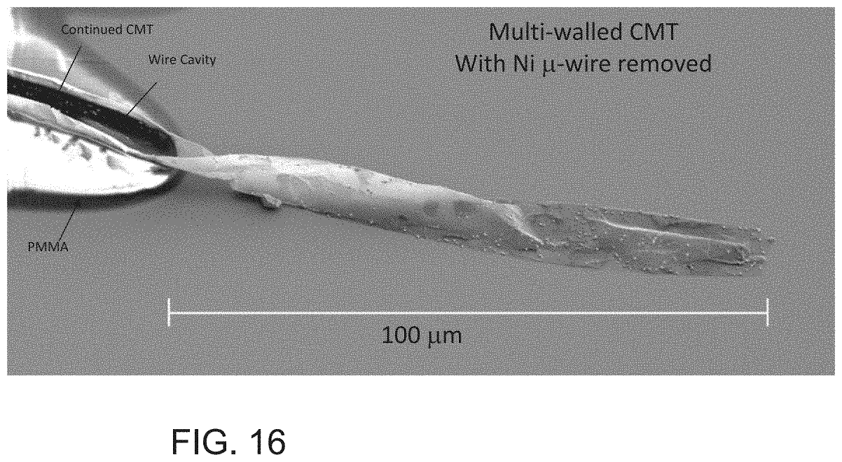

The example was repeated using 10 μm nickel wire. FIG. 15 shows a micrograph of the multi-layer assembly after light etching. As can be seen, the carbon microtube has an outer diameter of about 12-15 μm, resulting from deposition of multiple layers of sp² carbon. After etching away all the nickel with Transcene™ Cu etch, the microtube appears as shown in FIG. 16.

### Example 2

A copper wire, as for Example 1, is pulled through the hot zone of a furnace as illustrated in FIG. 5, for example from one spool onto another on different sides of the heated zone, to form a continuous and long film of graphene on the wire. This may not strictly meet the description of a carbon nanotube, wherein the planar sp² carbon lattice is rotationally continuous around the axis, but that is less important for tensile strength and electrical transport than that the lattice is continuous along the axial direction, which is achieved in this process.

It will be appreciated that variants of the above-disclosed and other features and functions, or alternatives thereof, may be combined into many other different systems or applications. Various presently unforeseen or unanticipated alternatives, modifications, variations or improvements therein may be subsequently made by those skilled in the art which are also intended to be encompassed by the following claims.

What is claimed is:

1. A method of forming a carbon microtube comprising:
providing a wire substrate in a heated furnace;
contacting a surface of the wire substrate in the heated furnace with a reducing gas;
forming a carbon microtube on the wire substrate by chemical vapor deposition of a carbon precursor in the heated furnace; and
removing the carbon microtube from the furnace.

2. The method of claim 1, further comprising: removing the substrate wire from the carbon microtube to provide a freestanding carbon microtube.

3. The method of claim 1, further comprising: forming an article which includes the carbon microtube, including embedding the microtube in a matrix material.

4. The method of claim 1, wherein the providing of the wire substrate in the heated furnace comprises progressively drawing at least a portion of the wire through a hot zone of the furnace.

5. The method of claim 1, wherein the wire has a diameter of no more than 100 μm, or no more than 20 μm.

6. The method of claim 1, wherein the wire has a length of at least 1 cm, or at least 20 cm, or at least 60 cm.

7. The method of claim 1, wherein the reducing gas comprises hydrogen.

8. The method of claim 1, wherein the carbon precursor is selected from the group consisting of C₁ to C₁₀ hydrocarbons and C₁ to C₁₀ alcohols.

9. The method of claim 1, wherein the carbon microtube is predominantly sp² carbon.

10. The method of claim 1, wherein the carbon microtube is a multi-layer carbon microtube.

11. The method of claim 1, wherein the wire substrate includes a catalytic metal which catalyzes the chemical vapor deposition of the carbon precursor.

12. A carbon microtube formed by the method of claim 1.

13. An article comprising a plurality of the carbon microtubes of claim 12.

14. A carbon microtube assembly comprising:
a core having a length of at least 10 cm;
a carbon microtube surrounding the core, the carbon microtube comprising at least one layer of predominantly sp² carbon, the at least one layer having an outer diameter of no more than 100 μm.

15. The carbon microtube assembly of claim 14, wherein the core includes a catalytic metal selected from the group consisting of copper, nickel, platinum group transition metals, 3d transition metals, and mixtures and alloys thereof.

16. The carbon microtube assembly of claim 14, wherein the core comprises a nickel surface and the carbon microtube comprises a plurality of layers of predominantly sp² carbon.

17. An article comprising the carbon microtube assembly of claim 14.

18. An apparatus for forming a cylindrical carbon structure comprising:
a furnace including a chamber which defines a hot zone;
a transport mechanism which progressively transports a wire through the hot zone;
a source of a reducing gas connected with the chamber; and
a source of a carbon precursor connected with the chamber, the carbon precursor being catalytically converted to a cylindrical carbon structure on the wire.

19. The apparatus of claim 18, wherein the transport mechanism includes a feed reel and a take-up reel, spaced by the hot zone, and a drive mechanism which drives the take-up reel.

20. The apparatus of claim 18, further comprising a heater which provides a temperature of at least 850° C. in the hot zone.
